(19) United States
(12) Patent Application Publication
(10) Pub. No.: US 2014/0299183 A1
(43) Pub. Date: Oct. 9, 2014

(54) ELECTRODE STRUCTURE ON A DEVICE AND METHOD OF FABRICATING THE SAME

(71) Applicants: DARFON MATERIALS CORPORATION, Tainan (TW); DARFON ELECTRONICS (SUZHOU) CO., LTD., Suzhou (CN)

(72) Inventors: Cheng-Ling Shih, Taoyuan (TW); Wei-Ting Chen, Taoyuan (TW); Kun-Chang Hsu, Taoyuan (TW)

(73) Assignees: DARFON MATERIALS CORPORATION, Tainan (TW); DARFON ELECTRONICS (SUZHOU) CO., LTD., Suzhou (CN)

(21) Appl. No.: 14/197,128

(22) Filed: Mar. 4, 2014

(30) Foreign Application Priority Data
Apr. 3, 2013 (CN) 201310116455.5

(51) Int. Cl. H01L 31/0224; H01L 31/18

(52) U.S. Cl. CPC H01L 31/022425; H01L 31/18
USPC 136/256; 438/98

(57) ABSTRACT

The invention discloses an electrode structure on a device and a method of fabricating the same. The invention respectively utilizes a stencil with a plurality of rows of parallel and hollowed grooves and a screen with a plurality of parallel bridge mesh areas and at least one strip mesh area to print a patterned metal paste corresponding to the electrode structure on a front surface of the device. The patterned metal paste is baked and then sintered to form the electrode structure.

### BACKGROUND OF THE INVENTION

1. Field of the Invention

The present invention relates to an electrode structure on a device and method of fabricating the same, especially to a front electrode on a photovoltaic device and method of fabricating the same.

2. Description of the Prior Art

An electrode structure can be formed on a surface of a device, such as an electronic device, an opto-electronic device, a photovoltaic device and so on. Taking the photovoltaic device for an example, a front electrode structure is formed on a front surface, that is, an incident plane of the photovoltaic device for collecting electrons or electron holes. The conventional front electrode structure includes a plurality of parallel finger electrodes with slim widths and at least one bus bar electrode perpendicular to the plurality of parallel finger electrodes with a thicker width. The bus bar electrode is for soldering the photovoltaic device with other photovoltaic device in a series connection.

The quality of the front electrodes decides the photoelectric transducing efficiency of the photovoltaic device. Fabrication of the front electrodes is that utilizing a screen twice to print the bus bar electrode with slim width and higher height in the prior art. However, according to the prior art, utilizing the screen to print twice is for printing the same pattern, and it may result in errors of position of the patterns. Fabrication of the front electrodes by utilizing the screen to print twice is described as follows in another prior art. The first screen printing is to form a bottom of the finger electrode, and the second screen printing is to form a top of the finger electrode and the bus bar electrode. However, according to the prior arts of twice screen printing, metal paste easily permeate into intersections between fibers of the screen, and it results in the corresponding pattern of the front electrodes being smudged. Therefore, a single electrode with uneven width is fabricated by utilizing the screen to print twice to fabricate the front electrodes in the prior art, and it results in defective front electrodes, especially in the slim finger electrodes. For improving the above-mentioned problem, as keeping the basic conductivity of the finger electrodes, the width of the finger electrodes should be increased, and a shielding rate of the front electrodes on the photovoltaic device is also increased so as to decrease the photoelectric transducing efficiency of the photovoltaic device.

In another prior art, fabrication of the front electrodes on the photovoltaic device is that utilizing a stencil to print the patterned metal paste corresponding to the front electrodes once. A plurality of corresponding finger electrodes and hollowed grooves of the bus bar electrode are formed on the stencil. However, metal strips between two neighboring hollowed grooves might be deformed during the stencil print operation, and it results in uneven width of the conductive strips made of metal paste. Besides, a plurality of vacant bridge portions of each hollowed groove can be formed in the stencil print operation in the prior art. However, metal paste might not flow to a bottom of the bridge portions easily, and it results in a defective printing. In addition, the bridge portions of the stencil require additional process, so that cost of the stencil print operation is increased.

Obviously, there is a need to improve fabrication of strip electrodes, especially to fabrication of the front electrode structure on the photovoltaic device. More particularly, it is necessary for improving the process of printing the patterned metal paste corresponding to the front electrode structure.

### SUMMARY OF THE INVENTION

The present invention relates to a method of fabricating an electrode structure on a device, especially to a method of fabricating a front electrode on a photovoltaic device. The front electrodes fabricated by the method in the present invention are provided with high quality and enhanced photoelectric transducing efficiency.

A method according to a preferred embodiment of the present invention is to fabricate an electrode structure on a surface of a device. The electrode structure includes a plurality of parallel strip electrodes and at least one bus bar electrode perpendicular to the plurality of parallel strip electrodes. The method includes utilizing a stencil with a plurality of rows of hollowed grooves arranged in parallel to print a first metal paste on the surface so as to form a plurality of rows of parallel first conductive strips. Each the hollowed groove is corresponding to one of the plurality of rows of parallel first conductive strips, and a bridge portion is disposed between the neighboring hollowed grooves of the stencil. The method further includes utilizing a screen with a plurality of rows of parallel bridge mesh areas and at least one strip mesh area to print a second metal paste on the surface so as to form a plurality of rows of parallel bridge conductive portions and at least one second conductive strip, wherein each bridge mesh area is corresponding to one of the plurality of rows of parallel bridge conductive portions, each strip mesh area is corresponding to one of the at least one second conductive strip, and each bridge conductive portion is connected to the two neighboring first conductive strips in the same row. The method further includes baking and sintering the plurality of rows of parallel first conductive strips, the plurality of rows of parallel bridge conductive portions and the at least one second conductive strip to form the plurality of parallel strip electrodes and the at least one bus bar electrode, wherein each strip electrode is composed of one row of sintered first conductive strips and the sintered bridge conductive portions in the same row, and each bus bar electrode is composed of one sintered second conductive strip.

According to the method of the preferred embodiment of the present invention, the plurality of rows of parallel bridge conductive portions and the at least one second conductive strip are formed and baked before the plurality of rows of parallel first conductive strips is formed.

According to another preferred embodiment of the present invention, an electrode structure is formed on a surface of a device. The electrode structure includes a plurality of strip electrodes and at least one bus bar electrode. Each strip electrode is composed of a row of spaced first conductive strips and the spaced bridge conductive portions in the same row, and each bridge conductive portion is connected to the two neighboring first conductive strips in the same row. Each bus bar electrode is connected to the plurality of strip electrodes. A plurality of rows of first conductive strips is formed by utilizing a stencil to print a first metal paste on the surface. Each bus bar electrode is composed of a second conductive strip. The at least one second conductive strip is formed by utilizing a screen to print a second metal paste on the surface.

The strip electrodes fabricated by the method of the present invention are provided with good resolution and high quality. The front electrodes fabricated by the method of the present invention are provided with high quality and enhanced photoelectric transducing efficiency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view of a stencil according to a first preferred embodiment of the present invention.

FIG. 2 is a top view of a device according to the first preferred embodiment of the present invention.

FIG. 3 is a top view of a screen according to the first preferred embodiment of the present invention.

FIG. 4 is a top view of the device printed by utilizing the stencil and the screen according to the first preferred embodiment of the present invention.

FIG. 5 is a partial cross-sectional diagram of the device along line A-A in FIG. 4 according to the first preferred embodiment of the present invention.

FIG. 6 is a top view of the device printed by utilizing the stencil and the screen and then being sintered according to the first preferred embodiment of the present invention.

FIG. 7 is a top view of the device printed by utilizing the screen according to a second preferred embodiment of the present invention.

FIG. 8 is a partial cross-sectional diagram of the device printed by utilizing the stencil and the screen along line A-A in FIG. 4 according to the second preferred embodiment of the present invention.

FIG. 9 is a top view of a stencil according to a third preferred embodiment of the present invention.

FIG. 10 is a top view of a device printed by utilizing the stencil according to the third preferred embodiment of the present invention.

FIG. 11 is a top view of a screen according to the third preferred embodiment of the present invention.

FIG. 12 is a top view of the device printed by utilizing the stencil and the screen according to the third preferred embodiment of the present invention.

FIG. 13 is a top view of the device printed by utilizing the stencil and the screen 6 and then being sintered according to the third preferred embodiment of the present invention.

FIG. 14 is a top view of the device printed by utilizing the screen according to the third preferred embodiment of the present invention.

FIG. 15 is a top view of a stencil according to a fourth preferred embodiment of the present invention.

FIG. 16 is a top view of a screen according to the fourth preferred embodiment of the present invention.

FIG. 17 is a top view of a device printed by utilizing the stencil and the screen and then being sintered according to the fourth preferred embodiment of the present invention.

### DETAILED DESCRIPTION

In the following detailed description of the preferred embodiments, reference is made to the accompanying drawings which form a part hereof, and in which is shown by way of illustration specific embodiments in which the invention may be practiced. In this regard, directional terminology, such as “top,” “bottom,” “front,” “back, ” etc., is used with reference to the orientation of the Figure(s) being described. The components of the present invention can be positioned in a number of different orientations. As such, the directional terminology is used for purposes of illustration and is in no way limiting. Accordingly, the drawings and descriptions will be regarded as illustrative in nature and not as restrictive.

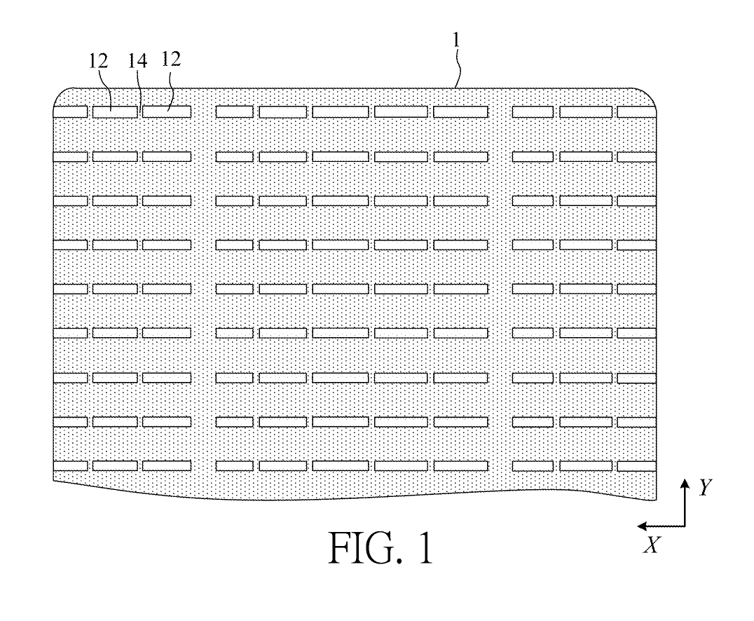

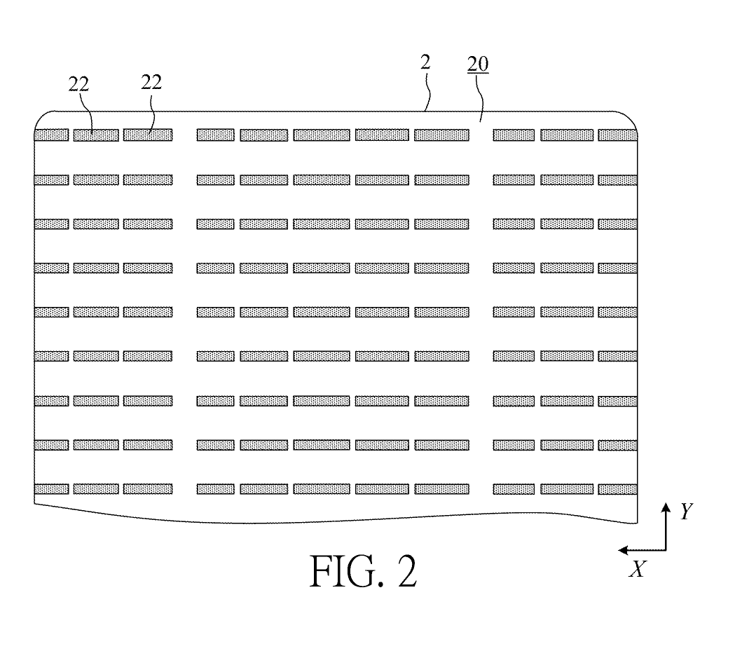

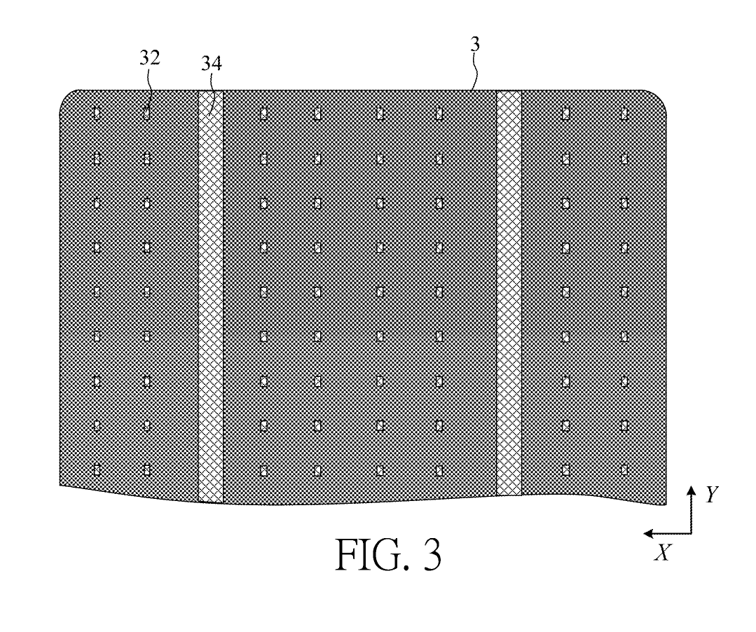

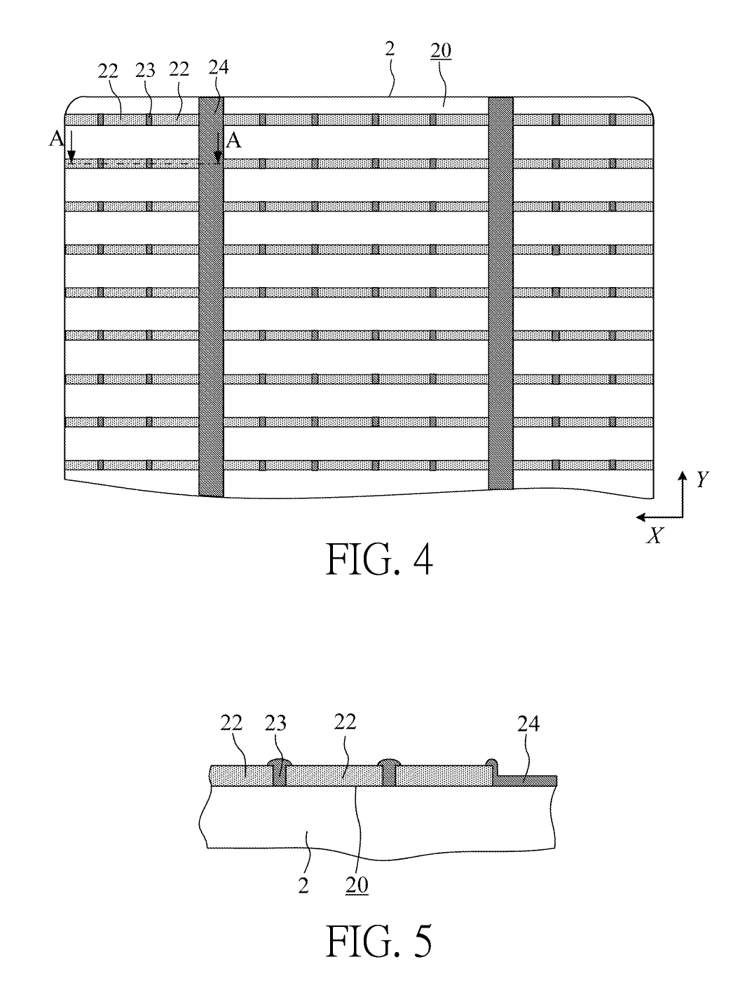

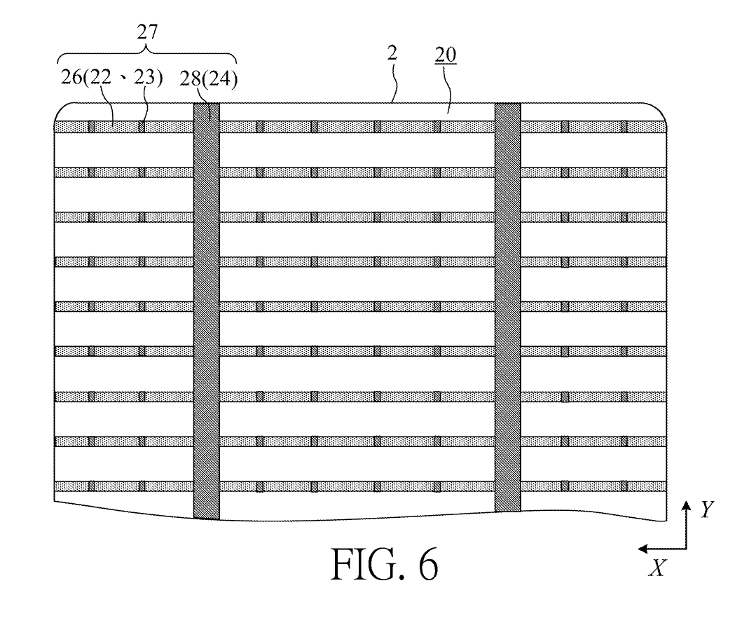

Please refer to FIG. 1 to FIG. 6, a manufacturing method and components of a first preferred embodiment are illustrated in these figures. FIG. 1 is a top view of a stencil 1 according to the first preferred embodiment of the present invention. FIG. 2 is a top view of a device 2 according to the first preferred embodiment of the present invention. FIG. 3 is a top view of a screen 3 according to the first preferred embodiment of the present invention. FIG. 4 is a top view of the device 2 printed by utilizing the stencil 1 and the screen 3 according to the first preferred embodiment of the present invention. FIG. 5 is a partial cross-sectional diagram of the device 2 along line A-A in FIG. 4 according to the first preferred embodiment of the present invention. FIG. 6 is a top view of the device 2 printed by utilizing the stencil 1 and the screen 3 and then being sintered according to the first preferred embodiment of the present invention. As shown in FIG. 6, an electrode structure 27 on a surface 20 of the device 2 is the finished manufacture. The electrode structure 27 includes a plurality of parallel strip electrodes 26 and at least one bus bar electrode 28 perpendicular to the plurality of parallel strip electrodes 26. The device 2 can be an electronic device, an opto-electronic device, a photovoltaic device, and so on. As the device 2 is a photovoltaic device and the surface 20 of the device is an incident plane, the electrode structure 27 can be a front electrode structure, and the strip electrodes 26 is a finger electrode.

Specifically, the photovoltaic device 2 can be a monocrystalline silicon photovoltaic device, a polycrystalline silicon photovoltaic device, an amorphous silicon membrane photovoltaic device, a microcrystalline silicon photovoltaic device, a cadmium sulphide (CdS) membrane photovoltaic device, a cadimium telluride (CdTe) membrane photovoltaic device, a copper indium selenide (CuInSe₂, CIS) membrane photovoltaic device, a copper indium gallium selenide (Cu(In, Ga)Se₂, CIGS) membrane photovoltaic device, a dye-sensitized (DSSC) membrane photovoltaic device or a gallium arsenide (GaAs) photovoltaic device.

The method of the first preferred embodiment of the present invention includes that preparing the stencil 1 with a plurality of rows of hollowed grooves 12 arranged in parallel, and the stencil 1 includes a bridge portion 14 disposed between two neighboring hollowed grooves 12 in the same row, as shown in FIG. 1. The plurality of rows of hollowed grooves 12 is substantially arranged parallel to a direction along axis X shown in FIG. 1, and projections of the plurality of rows of bridge portions 14 are aligned. That is, the neighboring rows of bridge portions 14 are arranged parallel to a direction along axis Y shown in FIG. 1. The stencil 1 can be made of metal material.

As shown in FIG. 2, the method further includes utilizing the stencil 1 to print a first metal paste on the surface 20 of the device 2 so as to form a plurality of rows of parallel first conductive strips 22. Each hollowed groove 12 is corresponding to one of the plurality of rows of parallel first conductive strips 22, and then the method further includes baking the plurality of rows of parallel first conductive strips 22.

As shown in FIG. 3, the method further includes preparing the screen 3 with a plurality of rows of parallel bridge mesh areas 32 and at least one strip mesh area 34. And then, as shown in FIG. 4, the method further includes utilizing the screen 3 to print a second metal paste on the surface 20 of the device 2 so as to form a plurality of rows of parallel bridge conductive portions 23 and at least one second conductive strip 24. Each bridge mesh area 32 is corresponding to one of the plurality of rows of parallel bridge conductive portions 23. Each strip mesh area 34 is corresponding to one of the at least one second conductive strip 24. Each bridge conductive portion 23 is connected to the two neighboring first conductive strips 22 in the same row. At last, the method further includes baking the plurality of rows of parallel bridge conductive portions 23 and the at least one second conductive strip 24.

As shown in FIG. 5, the stencil 1 is utilized to print the first metal paste to form the first conductive strips 22, and then the screen 3 is utilized to print the second metal paste to form the bridge conductive portions 23 and the second conductive strips 24. Each gap between the two neighboring first conductive strips is filled with the corresponding bridge conductive portion 23. An edge part of each second conductive strip 24 covers the connected first conductive strips 22, and an edge part of each bridge conductive portion 23 covers the neighboring first conductive strips 22. There is no gap between the second conductive strips 24 and the first conductive strips 22, and an edge part of each second conductive strip 24 covers the neighboring first conductive strips 22.

As shown in FIG. 6, at last, the method further includes sintering the plurality of rows of parallel first conductive strips 22, the plurality of rows of parallel bridge conductive portions 23 and the at least one second conductive strip 24 to form the plurality of parallel strip electrodes 26 and the at least one bus bar electrode 28, according to the first preferred embodiment. Each strip electrode 26 is composed of one row of sintered first conductive strips 22 and the sintered bridge conductive portions 23 in the same row, and each bus bar electrode 28 is composed of one sintered second conductive strip 24.

As shown in FIG. 6, an electrode structure 27 is formed on the surface 20 of the device 2 according to the first preferred embodiment of the present invention. The electrode structure 27 includes the plurality of strip electrodes 26 and the at least one bus bar electrode 28 perpendicular to the strip electrodes 26. Each strip electrode 26 is composed of a row of spaced first conductive strips 22 and the spaced bridge conductive portions 23 in the same row, and each bridge conductive portion 23 is connected to the two neighboring first conductive strips 22 in the same row. Each bus bar electrode 28 is perpendicularly connected to the plurality of strip electrodes 26. The method of fabricating the electrode structure 27 is reiterated as follows. First, utilize the stencil 1 shown in FIG. 1 to print the first metal paste on the surface 20 of the device 2 to form the plurality of first conductive strips 22. Second, utilize the screen 3 shown in FIG. 3 to print the second metal paste on the surface 20 of the device 2 to form the at least one second conductive strip 24 and the plurality of bridge conductive portions 23.

According to the embodiment of the present invention, the plurality of rows of first conductive strips 22 and the plurality of rows of bridge conductive strips 23 are baked and sintered to form a plurality of strip electrodes 27. The at least one second conductive strip 24 is baked and sintered to form the at least one bus bar electrode 28.

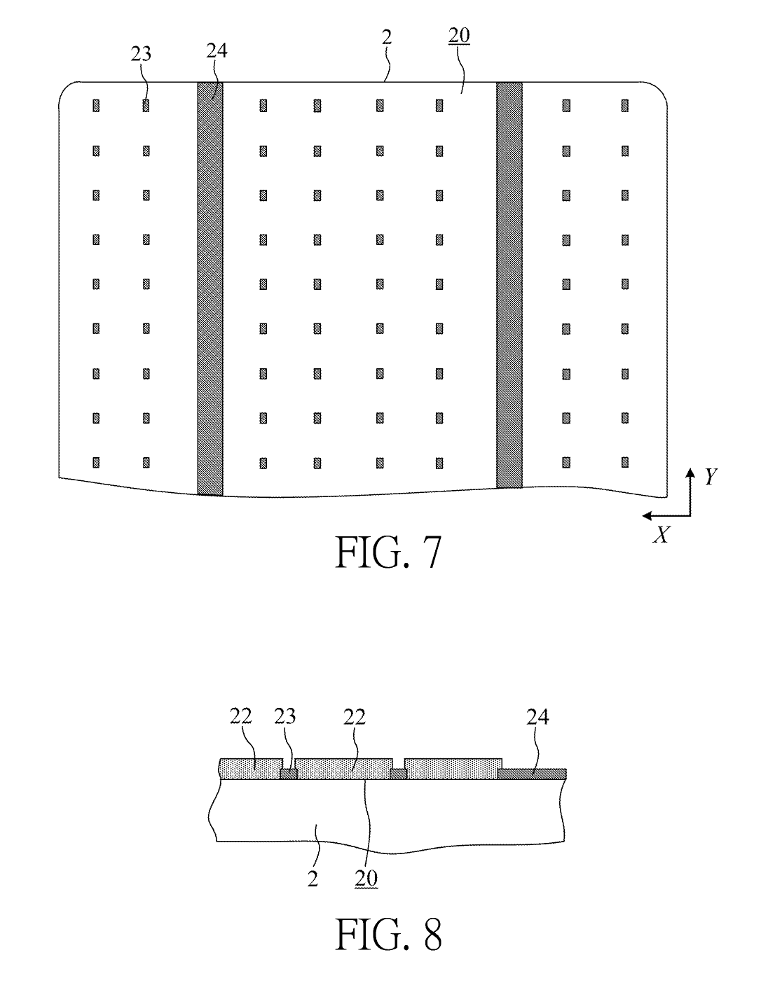

Please refer to FIG. 7. FIG. 7 is a top view of the device 2 printed by utilizing the screen 3 according to a second preferred embodiment of the present invention. The method according to the second preferred embodiment is described as follows. First, the method includes utilizing the screen 3 shown in FIG. 3 to print a second metal paste so as to form the plurality of rows of parallel bridge conductive portions 23 and at least one second conductive strip 24 on the surface 20 of the device 2, and then baking it to form a semi-finished manufacture shown in FIG. 7. Second, the method further includes utilizing the stencil 1 shown in FIG. 1 to print the first metal paste to form the plurality of rows of parallel first conductive strips 22, and then baking and sintering it to form a finished manufacture shown in FIG. 6.

Please refer to FIG. 8. FIG. 8 is a partial cross-sectional diagram of the device 2 printed by utilizing the stencil 1 and the screen 3 along line A-A in FIG. 4 according to the second preferred embodiment of the present invention. The finished manufacture is fabricated by the method of utilizing the screen 3 to print the second metal paste to form the bridge conductive portions 23 and the second conductive strips 24 and then utilizing the stencil 1 to print the first metal paste to form the first conductive strips 22, as shown in FIG. 8. Each bridge conductive portion 22 is appropriately connected to the two neighboring first conductive strips 22, and an edge part of each first conductive strip 22 covers an edge part of the neighboring bridge conductive portion 23. There is no gap between the first conductive strips 22 and the second conductive strip 24, and the edge part of each first conductive strip 22 covers an edge part of the neighboring second conductive strip 24. Thus, the finished manufacture fabricated by the method according to the second preferred embodiment is similar as the finished manufacture fabricated by the method according to the first preferred embodiment shown in FIG. 6, but the structure of the finished manufacture fabricated by the method according to the second preferred embodiment shown in FIG. 8 is different from the structure of the finished manufacture fabricated by the method according to the first preferred embodiment shown in FIG. 5.

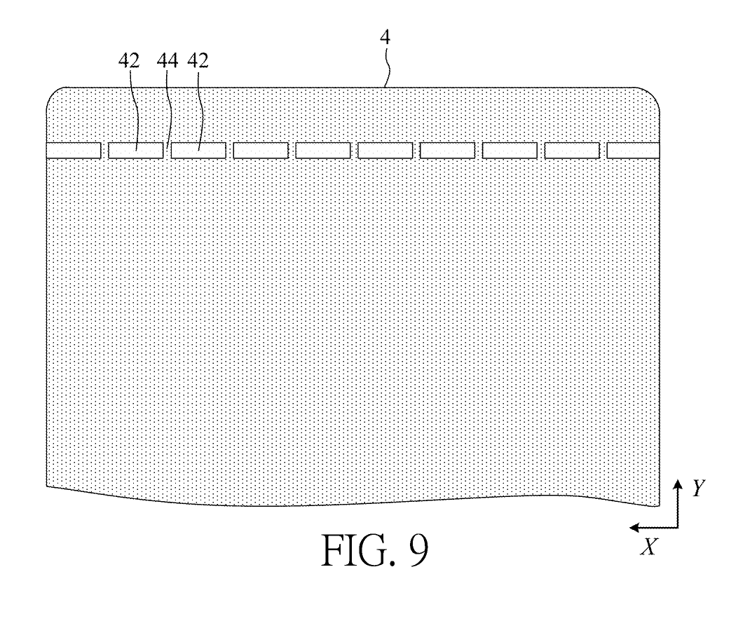

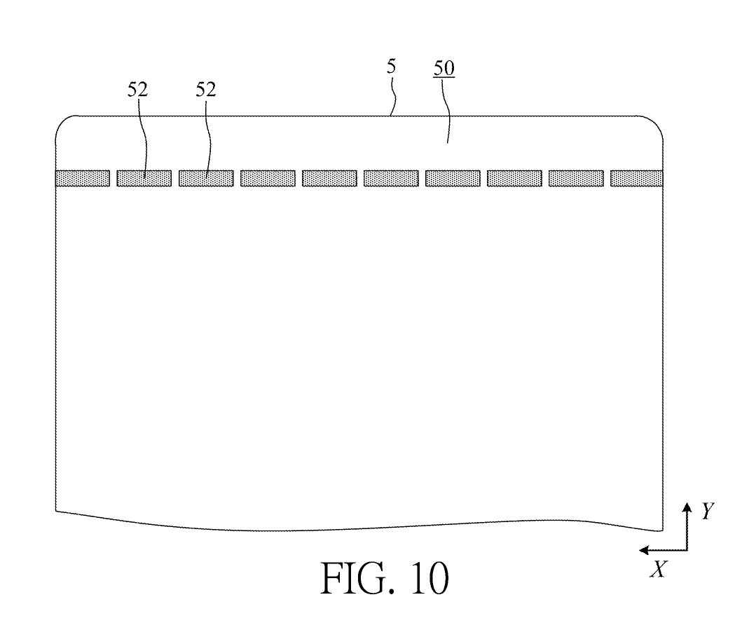

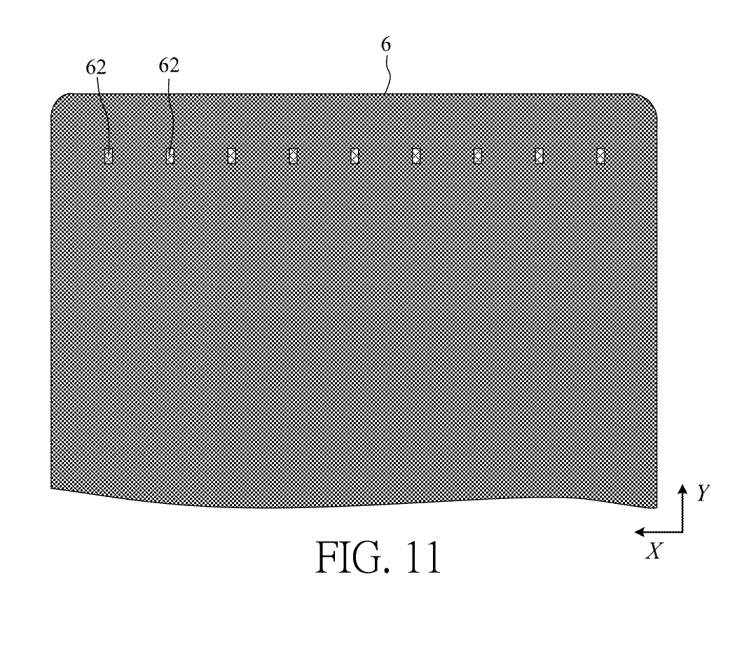

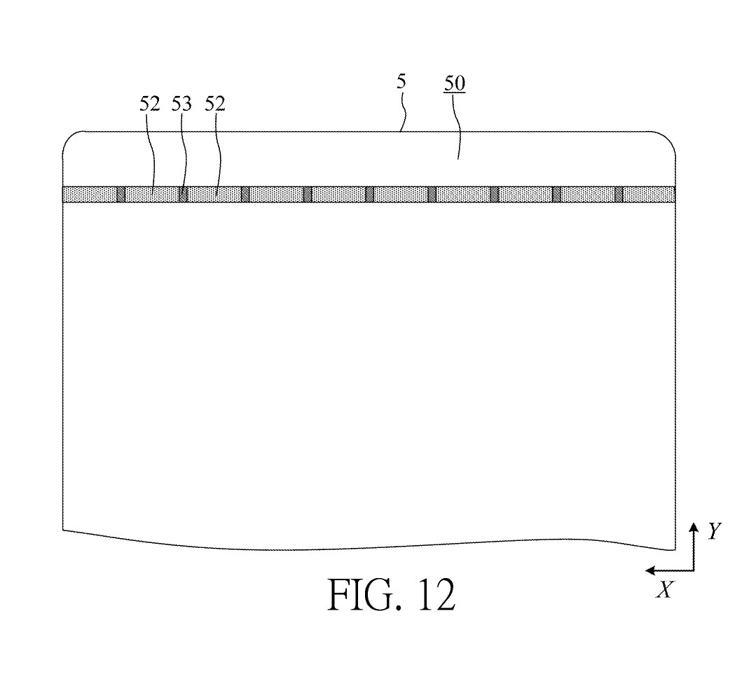

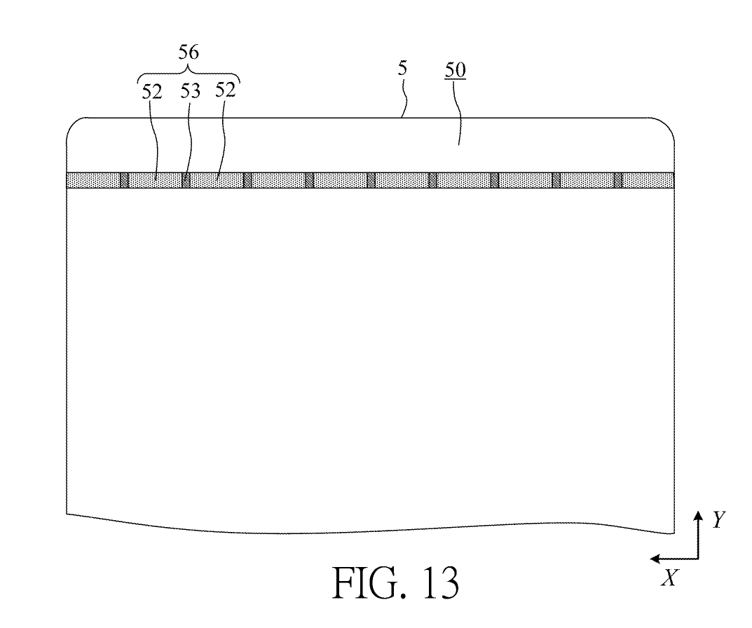

Please refer to FIG. 9 to FIG. 13. FIG. 9 is a top view of a stencil 4 according to a third preferred embodiment of the present invention. FIG. 10 is a top view of a device 5 printed by utilizing the stencil 4 according to the third preferred embodiment of the present invention. FIG. 11 is a top view of a screen 6 according to the third preferred embodiment of the present invention. FIG. 12 is a top view of the device 5 printed by utilizing the stencil 4 and the screen 6 according to the third preferred embodiment of the present invention. FIG. 13 is a top view of the device 5 printed by utilizing the stencil 4 and the screen 6 and then being sintered according to the third preferred embodiment of the present invention. The method and components are illustrated in the figures. The method according to the third preferred embodiment is to fabricate strip electrodes 56 on a surface 50 of the device 5. The device 5 can be an electronic device, an opto-electronic device, a photovoltaic device, and so on.

As shown in FIG. 9, a method according to the third preferred embodiment includes utilizing the stencil 4 with a row of parallel hollowed grooves 42 to print a first metal paste on the surface 50 of the device 5 to form a row of parallel conductive strips 52, as shown in FIG. 10. Each hollowed groove 42 is corresponding to a conductive strip 52. A bridge portion 44 is disposed between two neighboring hollowed grooves 42. The method according to the third preferred embodiment of the present invention further includes baking the row of parallel conductive strips 52.

And then, as shown in FIG. 11, the method according to the third preferred embodiment further includes utilizing the screen 6 with a row of bridge mesh areas 62 to print a second metal paste on the surface 50 of the device 5 so as to form a row of bridge conductive portions 53, shown in FIG. 12. Each bridge mesh area 62 is corresponding to one bridge conductive portion 53. Each bridge conductive portion 53 is connected to the two neighboring conductive strips 52. And then, the method according to the third preferred embodiment of the present invention further includes baking the row of parallel bridge conductive portions 53.

At last, the method according to the third preferred embodiment further includes baking the row of parallel conductive strips 52 and the bridge conductive portions 53 in the same row to form the strip electrode 56, as shown in FIG. 13. The strip electrode 56 is composed of the row of baked conductive strips 52 and the baked bridge conductive portions 53 in the same row.

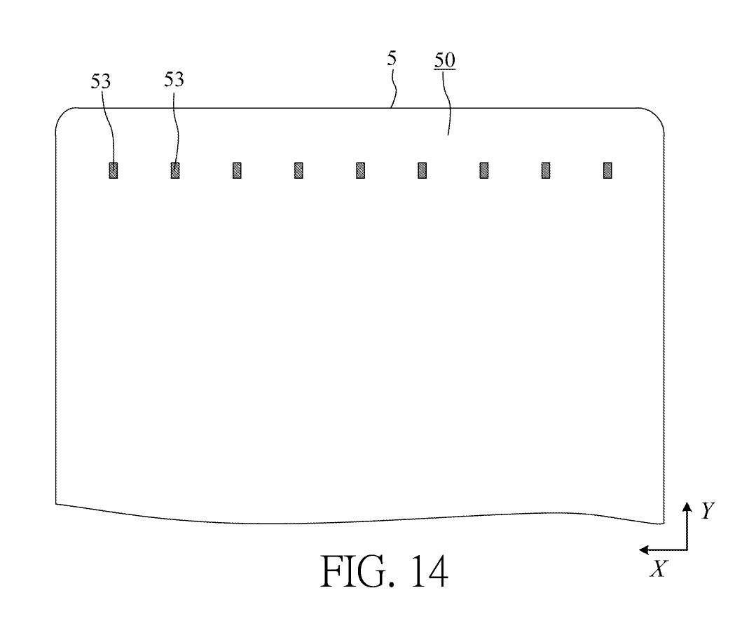

Please refer to FIG. 14. FIG. 14 is a top view of the device 5 printed by utilizing the screen 6 according to the third preferred embodiment of the present invention. Another method according to the third preferred embodiment is to utilize the screen 6 shown in FIG. 11 to print the second metal paste to form the row of bridge conductive portions 53 on the surface 50 of the device 5 and to bake it before the row of the conductive strips 52 are formed, as shown in FIG. 14. And then, the first metal paste is printed on the surface 5 of the device 50 to form the row of conductive strips 52 by the stencil 4 shown in FIG. 9, and it is baked to form the structure shown in FIG. 12.

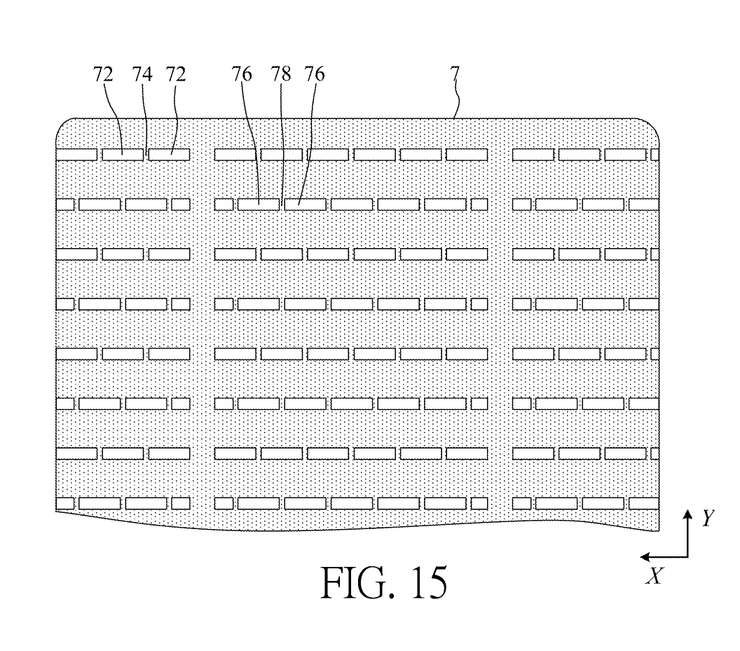

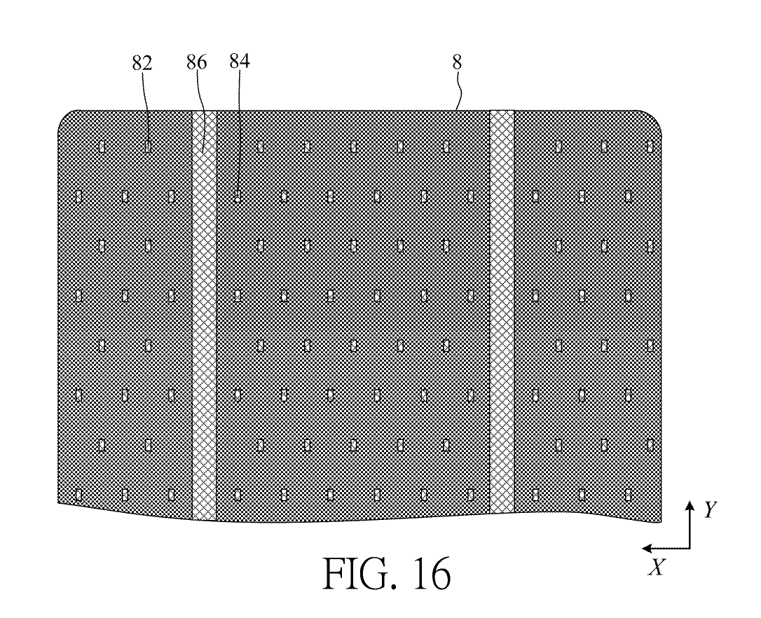

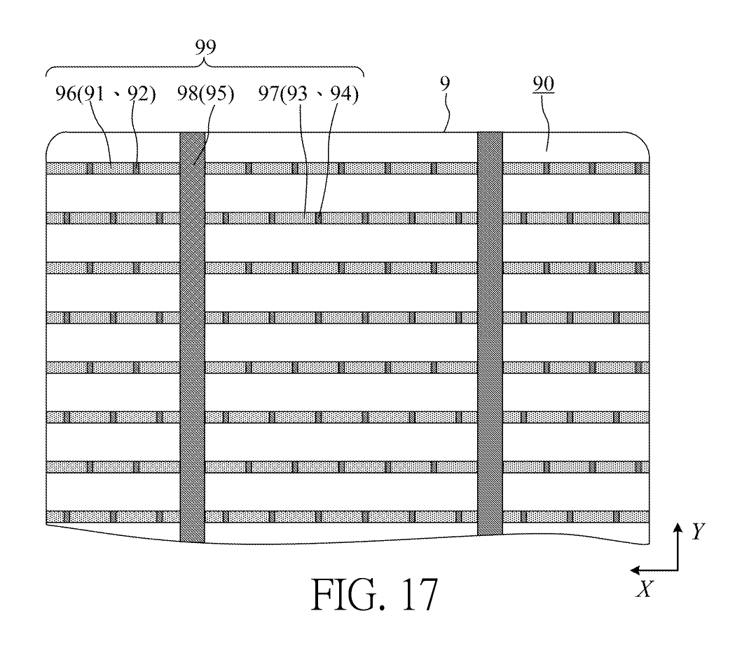

Please refer to FIG. 15 to FIG. 17. FIG. 15 is a top view of a stencil 7 according to a fourth preferred embodiment of the present invention. FIG. 16 is a top view of a screen 8 according to the fourth preferred embodiment of the present invention. FIG. 17 is a top view of a device 9 printed by utilizing the stencil 7 and the screen 8 and then being sintered according to the fourth preferred embodiment of the present invention. The method according to the fourth preferred embodiment and components are illustrated in the figures. The method according to the fourth preferred embodiment includes fabricating an electrode structure 99 on a surface 90 of the device 9. As shown in FIG. 17, the electrode structure 99 on the surface 90 of the device 9 is the finished manufacture according to the fourth embodiment of the present invention. The electrode structure 99 includes a plurality of rows of first strip electrodes 96, a plurality of rows of second strip electrodes 97, and at least one bus bar electrode 98 separated from the first strip electrodes 96 and the second strip electrodes 97. Each bus bar electrode 98 is connected to the first strip electrodes 96 and the second strip electrodes 97. The device 5 can be an electronic device, an opto-electronic device, a photovoltaic device, and so on.

The method of the fourth preferred embodiment is described as follows. As shown in FIG. 15, the method includes preparing the stencil 7 including a plurality of rows of first hollowed grooves 72 and a plurality of rows of second hollowed grooves 76. A first bridge portion 74 is disposed between the two neighboring first hollowed grooves 72, and a second bridge portion 78 is disposed between the two neighboring second hollowed grooves 76. According to the fourth preferred embodiment, each row of first hollowed grooves 72 and each row of second hollowed grooves 76 are substantially arranged parallel to a direction along axis X shown in FIG. 15, and projections on the direction along axis X of the plurality of rows of first bridge portions 74 and the plurality of rows of second bridge portions 78 are intersected. According to another method of the fourth preferred embodiment, the projections on the direction along axis X of the plurality of rows of first bridge portions 74 and the plurality rows of second bridge portions 78 are aligned. It is quite similar to the neighboring bridge portions 14 of the stencil 1 shown in FIG. 1, which are substantially parallel to the direction along axis Y. The stencil 7 can be made of metal material.

As shown in FIG. 16, the method further includes preparing the screen 8 including a plurality of rows of first bridge mesh areas 82, a plurality of rows of second bridge mesh areas 84 and at least one strip mesh area 86. For coordinating with the stencil 7 shown in FIG. 15, projections on the direction along axis X of the plurality of rows of first bridge mesh areas 82 and the plurality of rows of second bridge mesh areas 84 are intersected. According to another method of the fourth preferred embodiment, the projections on the direction along axis X of the plurality of rows of first bridge mesh areas 82 and the plurality of rows of second bridge mesh areas 84 are aligned, it is quite similar to the neighboring bridge mesh areas 32 of the screen 3 shown in FIG. 3, which are substantially parallel to the direction along axis Y.

The method of the fourth preferred embodiment is described as follows. First, the method further includes utilizing the stencil 7 to print a first metal paste on the surface 90 of the device 9 to form a plurality of rows of first conductive strips 91 and a plurality of rows of second conductive strips 93. Each first hollowed groove 72 is corresponding to one first conductive strip 91, and each second hollowed groove 76 is corresponding to one first conductive strip 93. And then, the method further includes utilizing the screen 8 to print a second metal paste on the surface 90 of the device 9 to form a plurality of first bridge conductive portions 92, a plurality of second bridge conductive portions 94 and at least one third conductive strip 95. Each first bridge mesh area 82 is corresponding to one first bridge conductive portion 92, each second bridge mesh area 84 is corresponding to one second bridge conductive portion 94, and each strip mesh area 86 is corresponding to one third conductive strip 95. Each first bridge conductive portion 92 is connected to the two neighboring first conductive strips 91, and each second bridge conductive portion 94 is connected to the two neighboring second conductive strips 93. The row of first conductive strips 91 and the row of first bridge conductive portions 92 are baked and sintered to form the first strip electrode 96, the row of second conductive strips 93 and the row of second bridge conductive portions 94 are baked and sintered to form the second strip electrode 97, and the bus bar electrode 98 is baked and sintered to form the third conductive strip 95 so as to form the structure shown in FIG. 17.

According to an embodiment, the printing procedure of utilizing the stencil 7 is processed before the printing procedure of utilizing the screen 8 so that an edge part of each third conductive strip 95 covers the first conductive strips 91 and the second conductive strips 93 connected to the corresponding third conductive strip 95, an edge part of each first bridge conductive portion 92 covers the neighboring first conductive strips 91, and an edge part of each second bridge conductive portion 94 covers the neighboring second conductive strips 93.

According to another embodiment, the printing procedure of utilizing the screen 8 is processed before the printing procedure of utilizing the stencil 7 so that the edge part of the first conductive strip 91 covers the connected third conductive strip 95 or the neighboring bridge conductive portions 92, and the edge part of each second conductive strip 93 covers the connected third conductive strip 95 or the neighboring second bridge conductive portions 94.

The width resolution of the strip electrodes (26, 56, 96 or 97) fabricated by the above-mentioned methods according to the preferred embodiments of the present invention is about 10 to 45 μm, the strip electrodes (26, 56, 96 or 97) has uniform width and high quality.

According to the different embodiments, a thickness of each bridge portion (14, 44, 74 or 78) is equal to the thickness of the stencil (1, 4 or 7). That is, each bridge portion (14, 44, 74 or 78) does not need to be processed to thinning. Therefore, the stencil (1, 4 or 7) utilized in the methods of the present invention has lower cost in contrast to the prior art.

According to the different embodiments, the first metal paste and the second metal paste can be conductive paste made of aluminum, silver, cooper, gold, platinum, palladium, aluminum alloy, silver alloy, cooper alloy, gold alloy, platinum alloy, palladium alloy, powder of the mixture of the combination thereof, or other commercial conductive metal paste. In practical application, the first metal paste and the second metal paste can be made of the same metal material.

In contrast to the prior art, the strip electrodes fabricated by the method of the present invention are provided with good resolution and high quality. The front electrodes fabricated by the method of the present invention are provided with high quality and enhanced photoelectric transducing efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating an electrode structure on a surface of a device, the electrode structure comprising a plurality of parallel strip electrodes and at least one bus bar electrode perpendicular to the plurality of parallel strip electrodes, the method comprising:
utilizing a stencil with a plurality of rows of hollowed grooves arranged in parallel to print a first metal paste on the surface so as to form a plurality of rows of parallel first conductive strips, wherein each hollowed groove is corresponding to one of the plurality of rows of parallel first conductive strips, and a bridge portion is disposed between the neighboring hollowed grooves of the stencil;
utilizing a screen with a plurality of rows of parallel bridge mesh areas and at least one strip mesh area to print a second metal paste on the surface so as to form a plurality of rows of parallel bridge conductive portions and at least one second conductive strip, wherein each bridge mesh area is corresponding to one of the plurality of rows of parallel bridge conductive portions, each strip mesh area is corresponding to one of the at least one second conductive strip, and each bridge conductive portion is connected to the two neighboring first conductive strips in the same row; and
baking and sintering the plurality of rows of parallel first conductive strips, the plurality of rows of parallel bridge conductive portions and the at least one second conductive strip to form the plurality of parallel strip electrodes and the at least one bus bar electrode, wherein each strip electrode is composed of one row of sintered first conductive strips and the sintered bridge conductive portions in the same row, and each bus bar electrode is composed of one sintered second conductive strip.

2. The method of claim 1, wherein a thickness of each bridge portion and a thickness of the stencil are identical.

3. The method of claim 1, wherein the plurality of rows of parallel first conductive strips is formed and baked before the plurality of rows of parallel bridge conductive portions and the at least one second conductive strip are formed, or the plurality of rows of parallel bridge conductive portions and the at least one second conductive strip are formed and baked before the plurality of rows of parallel first conductive strips is formed.

4. A method of fabricating a strip electrode on a surface of a device, the method comprising:
utilizing a stencil with a row of hollowed grooves to print a first metal paste on the surface to form a row of conductive strips, wherein each hollowed groove is corresponding to one of the row of conductive strips, and a bridge portion is disposed between the neighboring hollowed grooves of the stencil;
utilizing a screen with a row of bridge mesh areas to print a second metal paste on the surface to form a row of bridge conductive portions, wherein each bridge mesh area is corresponding to one of the row of bridge conductive portions, and each bridge conductive portion is connected to the two neighboring conductive strips; and
baking and sintering the row of conductive strips and the row of bridge conductive portions to form the strip electrode, wherein the strip electrode is composed of the row of sintered conductive strips and the row of sintered bridge conductive portions.

5. The method of claim 4, wherein a thickness of each bridge portion and a thickness of the stencil are identical.

6. The method of claim 4, wherein the row of conductive strips is formed and baked before the row of bridge conductive portions is formed, or the row of bridge conductive portions is formed and baked before the row of conductive strips is formed.

7. An electrode structure formed on a surface of a device, the electrode structure comprising:
a plurality of strip electrodes, each strip electrode being composed of a row of spaced first conductive strips and a row of spaced bridge conductive portions, and each bridge conductive portion is connected to the two neighboring first conductive strips in the same row; and
at least one bus bar electrode connected to the plurality of strip electrodes, each bus bar electrode being composed of a second conductive strip;
wherein a plurality of rows of first conductive strips is formed by utilizing a stencil to print a first metal paste on the surface, and the second conductive strip and a plurality of rows of spaced bridge conductive portions is formed by utilizing a screen to print a second metal paste on the surface.

8. The electrode structure of claim 7, wherein the plurality of strip electrodes is arranged in parallel, and the at least one bus bar electrode is perpendicular to the plurality of strip electrodes.

9. The electrode structure of claim 7, wherein the plurality of rows of first conductive strips and the plurality of rows of spaced bridge conductive portions are baked and sintered to form the plurality of strip electrodes, the at least one second conductive strip is baked and sintered to form the at least one bus bar electrode.

10. The electrode structure of claim 7, wherein an edge part of each second conductive strip covers the connected first conductive strips, and an edge part of each bridge conductive portion covers the neighboring first conductive strips.

11. The electrode structure of claim 7, wherein an edge part of each first conductive strip covers the connected second constructive strip or the neighboring bridge conductive portions.

12. A method of fabricating an electrode structure on a surface of a device, the electrode structure comprising a first strip electrode, a second strip electrode and a bus bar electrode, the first strip electrode and second strip electrode being separated from each other, the bus bar electrode being connected to the first strip conductive and the second conductive strip, the method comprising:
preparing a stencil comprising a row of first hollowed grooves and a row of second hollowed grooves, wherein a first bridge portion is disposed between the two neighboring first hollowed grooves, and a second bridge portion is disposed between the two neighboring second hollowed grooves;
preparing a screen comprising a row of first bridge mesh areas, a row of second bridge mesh areas and a strip mesh area;
utilizing the stencil to print a first metal paste on the surface so as to form a row of first conductive strips and a row of second conductive strips, wherein each of the first hollowed grooves is corresponding to one of the row of first conductive strips, and each of the second hollowed grooves is corresponding to one of the row of second conductive strips; and
utilizing the screen to print a second metal paste on the surface so as to form a row of first bridge conductive portions, a row of second bridge portions and a third conductive strip, wherein each of the first bridge mesh areas is corresponding to one of the row of first bridge conductive portions, and each of the second bridge mesh areas is corresponding to one of the row of second bridge conductive portions, the strip mesh area is corresponding to the third conductive strip, each of the first bridge conductive portions is connected to the two neighboring first conductive strips, and each of the second bridge conductive portions is connected to the two neighboring second conductive strips;
wherein the first strip electrode is composed of the row of first conductive strips and the row of first bridge conductive portions, the second strip electrode is composed of the row of second conductive strips and the row of second bridge conductive portions, and the bus bar electrode is composed of the third conductive strip.

13. The method of claim 12, wherein the row of first conductive strips and the row of first bridge conductive portions are baked and sintered to form the first strip electrode, the row of second conductive strips and the row of second bridge conductive portions are baked and sintered to form the second strip electrode, and the third conductive strip are baked and sintered to form the bus bar electrode.

14. The method in claim 12, wherein a thickness of each first bridge portion, a thickness of each second bridge portion and a thickness of the stencil are identical.

15. The method in claim 12, wherein the row of first conductive strips and the row of second conductive strips are formed and baked before the row of first bridge conductive portions, the row of second bridge conductive portions and the third conductive strips are formed.

16. The method in claim 12, wherein the row of first bridge conductive portions, the second bridge conductive portions and the third conductive strips are formed and baked before the row of first conductive strips and the row of conductive strips are formed.

17. The method in claim 12, wherein utilizing the stencil to print the first metal paste on the surface is processed before utilizing the screen to print the second metal paste on the surface so that an edge part of the third conductive strip covers the first conductive strips and the second conductive strips connected to the third conductive strip, an edge part of each first bridge conductive portion covers the neighboring first conductive strips, and an edge part of each second bridge conductive portion covers the neighboring second conductive strips.

18. The method in claim 12, wherein utilizing the screen to print the second metal paste on the surface is processed before utilizing the stencil to print the first metal paste on the surface so that an edge part of each first conductive strip covers the connected third conductive strip or the neighboring first bridge conductive portions, and an edge part of each second conductive strip covers the connected third conductive strip or the neighboring second bridge conductive portions.

19. The method in claim 12, wherein the row of first hollowed grooves and the row of second hollowed grooves are substantially arranged parallel to a predetermined direction, projections on the predetermined direction of the row of first bridge portions and the row of second bridge portions are aligned or intersected.
